(19) United States
(12) Patent Application Publication
(10) Pub. No.: US 2018/0159354 A1
(43) Pub. Date: Jun. 7, 2018

(54) ELECTRONIC DEVICE CAPABLE OF COMMUNICATING BY LI-FI

(71) Applicant: OLEDCOMM, Velizy Villacoublay (FR)

(72) Inventors: Jorge GARCIA-MARQUEZ, Montigny Le Bretonneux (FR); Suat TOPSU, Versailles (FR); Huetzin PEREZ OLIVAS, Versailles (FR)

(73) Assignee: OLEDCOMM, Velizy Villacoublay (FR)

(21) Appl. No.: 15/576,460

(22) PCT Filed: Jun. 17, 2016
(86) PCT No.: PCT/EP2016/064069

§ 371 Date: Nov. 22, 2017

(30) Foreign Application Priority Data
Jun. 18, 2015 (FR) 15 55599

(51) Int. Cl. H02J 7/02; H02J 7/35; H01L 35/30; H04B 10/116; H04B 10/50

(52) U.S. Cl. CPC H02J 7/025; H02J 7/35; H05B 37/0272; H04B 10/116; H04B 10/502; H01L 35/30

(57) ABSTRACT

An electronic device capable of communicating by Li-Fi and comprising:—at least one light emitting diode (4) intended to emit Li-Fi signals;—energy recovery means (10) intended to recover thermal energy produced by the light emitting diode and to generate, from the recovered thermal energy, a first electrical energy supply of the electronic device.

The invention relates to an electronic device capable of operating using Li-Fi and that is designed to harvest some of the thermal energy produced by a light-emitting diode used to emit Li-Fi signals.

### BACKGROUND OF THE INVENTION

The use of Li-Fi (for “Light Fidelity”) technology to implement wireless communication has many advantages: availability of the optical spectrum, absence of electromagnetic interference, cost, etc.

Moreover, by virtue in particular of the development of light-emitting diodes (LEDs) having very high switching capabilities and of photodiodes having very rapid response times, it is possible with Li-Fi to transmit and receive data at a significantly higher rate than the rate offered, for example, by Wi-Fi (for “Wireless Fidelity”) technology.

Li-Fi technology is thus perfectly suited to transmitting and receiving music, videos, Internet data, measurement data (temperature, brightness, etc.), alarms (fire, presence of toxic vapors, etc.), to networking sensors or other types of devices, etc.

### OBJECT OF THE INVENTION

The object of the invention is to reduce the electrical consumption of an electronic device capable of communicating by Li-Fi.

### SUMMARY OF THE INVENTION

In order to achieve this aim, an electronic device capable of communicating by Li-Fi is proposed, the electronic device including:
at least one light-emitting diode intended to emit Li-Fi signals;
energy harvesting means intended to harvest thermal energy produced by the light-emitting diode and to generate, from the harvested thermal energy, a first electrical energy supply for the electronic device.

By using the first electrical energy to at least partially supply the electronic device, the input of electrical energy required for the operation of the electronic device, and therefore the electrical consumption of the electronic device, is reduced.

### BRIEF DESCRIPTION OF THE DRAWINGS

The invention will be better understood in the light of the following description with reference to the figures of the appended drawings, in which:

FIG. 1 shows a partially cut-away view of an electronic device according to a first embodiment of the invention, which device is in this case a lighting device of a first type;

FIG. 2 shows energy harvesting means of the electronic device according to the first embodiment of the invention;

FIG. 3 shows a generic electronic module integrated into the electronic device according to the first embodiment of the invention;

FIG. 4 shows an electronic device according to a second embodiment of the invention, which device is in this case a lighting device of a second type;

FIG. 5 shows an electronic device according to a third embodiment of the invention, which device is in this case a tablet;

FIG. 6 shows an electronic device according to a fourth embodiment of the invention, which device is in this case a measuring device;

FIG. 7 shows an electronic device according to a fifth embodiment of the invention, which device is in this case a geolocation device;

FIG. 8 shows an electronic device according to a sixth embodiment of the invention, which device is in this case a portable speaker;

FIG. 9 shows an electronic device according to a seventh embodiment of the invention;

FIG. 10 shows a network of electronic devices of the invention that are interconnected and communicate with one another by Li-Fi.

### DETAILED DESCRIPTION OF THE INVENTION

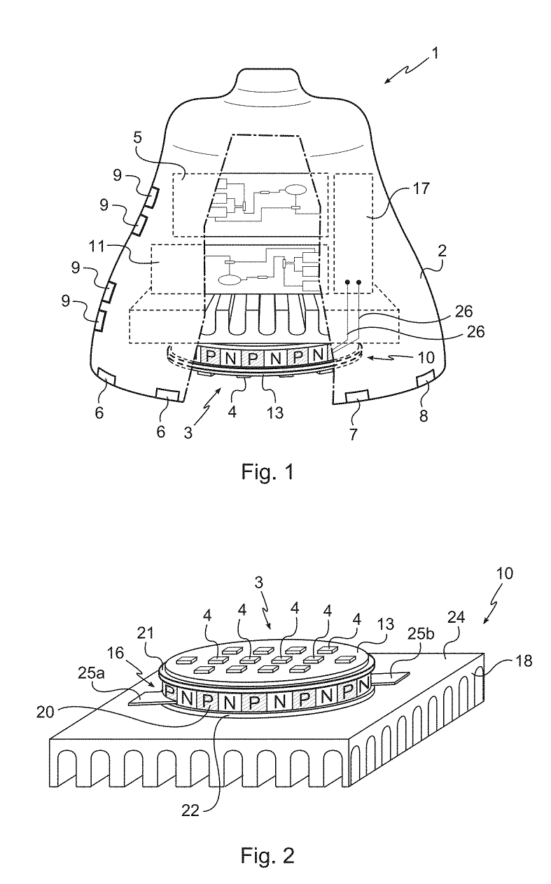

With reference to FIGS. 1 to 3, the electronic device capable of communicating by Li-Fi according to a first embodiment of the invention is here a lighting device of a first type, in this case a light-emitting diode lamp or LED lamp 1.

The LED lamp 1 includes a casing inside which are integrated a panel 3 of first light-emitting diodes 4, a light-emitting diode driver 5 (or LED driver), second light-emitting diodes 6, a first photodiode 7, a second photodiode 8, a plurality of sensors and of detectors 9, energy harvesting means 10 and an electronic module 11.

The panel 3 of first light-emitting diodes 4 includes a thermally conductive plate 13 on which the first light-emitting diodes 4 are arranged.

The first light-emitting diodes 4 are designed to emit Li-Fi signals in the visible spectrum.

The LED driver 5 is used to supply the light-emitting diodes 4, thereby enabling the LED lamp 1 to illuminate its environment.

The second light-emitting diodes 6 are designed to emit Li-Fi signals in the infrared spectrum.

The first photodiode 7 is designed to receive Li-Fi signals in the visible spectrum and the second photodiode 8 is designed to receive Li-Fi signals in the infrared spectrum.

The plurality of sensors and of detectors 9 includes a plurality of sensors and detectors from the following sensors and detectors: temperature sensor, humidity sensor, anemometer sensor, electrical consumption sensor, particle detector, infrared presence detector, motion detector, proximity sensor, biometric sensor (image of the iris, etc.), brightness sensor, smoke detector, radiometric parameter sensor, photometric parameter sensor, etc.

The plurality of sensors and of detectors 9 perform various measurements of parameters of the environment of the LED lamp 1.

The energy harvesting means 10 are intended to harvest thermal energy produced by the first light-emitting diodes 4 of the panel 3 of the LED lamp 1 and to generate, from the harvested thermal energy, a first electrical energy supply for the LED lamp 1.

The energy harvesting means 10 include a Peltier-type thermoelectric cell 16, a thermal-energy-harvesting unit 17 and a heat sink 18.

“Peltier-type thermoelectric cell” is understood to mean more precisely here a cell making it possible to generate, through an effect reciprocal to the Peltier effect, termed the Seebeck effect, an electrical potential difference from a temperature difference.

The thermoelectric cell 16 comprises a set of semiconductors 20 comprising semiconductors doped N-type and semiconductors doped P-type. The semiconductors are arranged between a thermally conductive hot plate 21 and a thermally conductive cold plate 22. The hot plate 21 is positioned in such a way that heat produced by the first light-emitting diodes 4 of the panel 3 heats the hot plate 21.

In this case, the panel 3 of first light-emitting diodes 4 is placed directly on the hot plate 21 of the thermoelectric cell 16.

The heat sink 18, here a finned radiator, is for its part arranged in such a way as to establish a thermal conduction relationship with the cold plate 22 of the thermoelectric cell 16 in order to promote cooling of the cold plate 22.

In this case, the cold plate 22 of the thermoelectric cell is placed directly on a face of a base 24 of the heat sink 18.

Thus, when the first light-emitting diodes 4 are supplied, a temperature difference is established between the hot plate 21 and the cold plate 22. The semiconductor assembly 20 then generates, through the Seebeck effect, a potential difference between the two conductive tabs 25a and 25b.

The two conductive tabs 25 are linked to the thermal-energy-harvesting unit 17 by two electrical wires 26. The thermal-energy-harvesting unit 17 generates, from this potential difference, an electric supply voltage and an electric supply current that constitute the first electrical energy supply for the LED lamp 1.

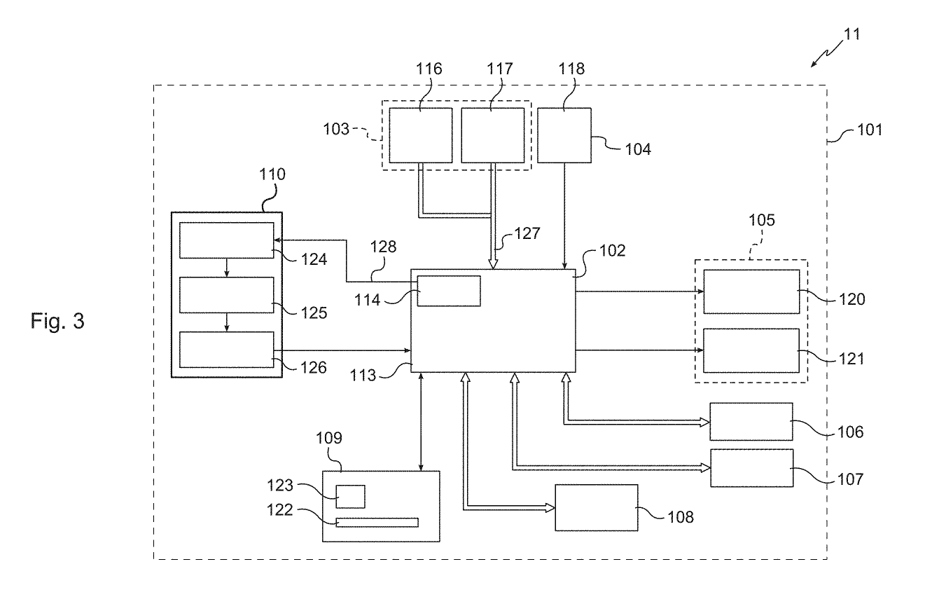

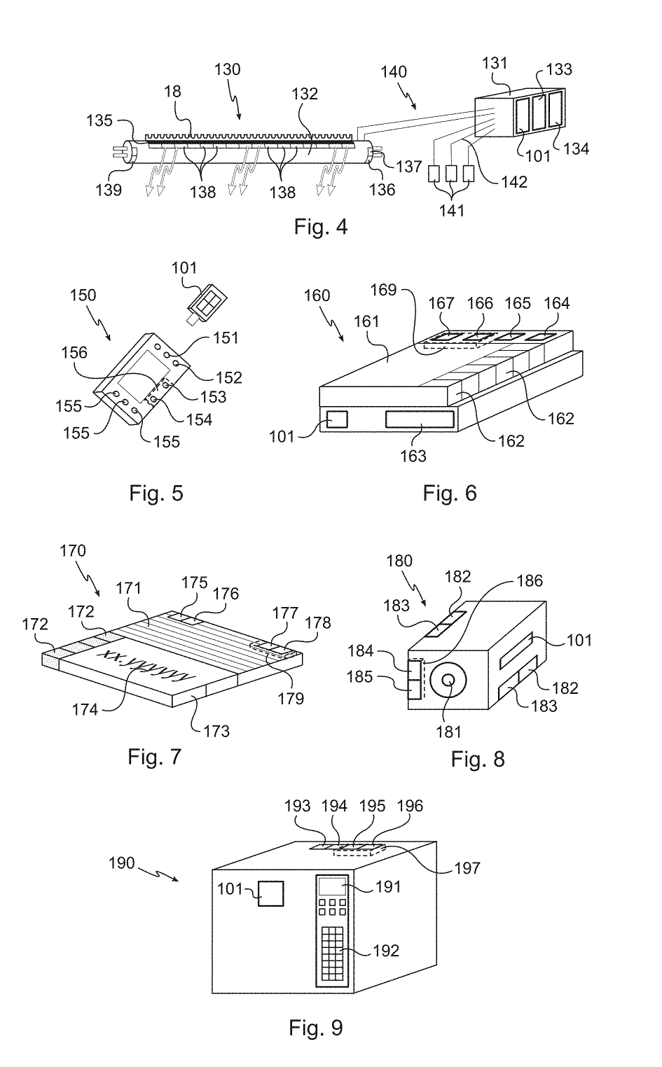

With reference to FIG. 3, the electronic module 11 includes a generic module 101 designed to be fitted in different electronic appliances or devices capable of communicating by Li-Fi. The generic module 101 is thus fitted in the LED lamp 1, but also in the other electronic devices visible in FIGS. 4 to 10 of the application and described later in this description.

The generic module 101 of the LED lamp 1 is supplied by the first electrical energy supply.

The generic module 101 includes an electrical board on which are mounted a certain number of electrical components grouped into a processing module 102, a first Li-Fi reception module 103, a second Li-Fi reception module 104, a Li-Fi transmission module 105, a memory module 106, a user interface 107, an external control interface 108, a measurement interface 109 and a light-energy-harvesting module 110.

The processing module 102 includes a microcontroller 113 and components enabling the microcontroller 113 to operate (clock, etc.). The microcontroller 113 is connected to all of the various modules and interfaces listed above. The microcontroller 113 manages the operation of these modules and interfaces, controls the transmission and the reception of Li-Fi signals by the LED lamp 1, and performs a certain number of processing operations on data originating from these modules and interfaces and on the Li-Fi signals.

Energy management means 114 are programmed into the microcontroller 113.

The first Li-Fi reception module 103 includes a first Li-Fi signal receiver 116 and a second Li-Fi signal receiver 117. The first receiver 116 is a visible-light receiver. The second receiver 117 is an infrared-light receiver.

The first receiver 116 is connected to the first photodiode 7 of the LED lamp 1. The second receiver 117 is connected to the second photodiode 8 of the LED lamp 1.

The first receiver 116 and the second receiver 117 each include means for acquiring and means for shaping the Li-Fi signals received by the photodiodes to which they are connected, which means make it possible to convert the received Li-Fi signals into digital signals that are able to be used by the microcontroller 113.

The first receiver 116 and the second receiver 117 have a low electrical energy consumption and are designed to receive data at a low rate, at a frequency here of between 0 and 100 kHz.

The second Li-Fi reception module 104 includes a third Li-Fi signal receiver 118. The third receiver 118 is connected to the first photodiode 7 and to the second photodiode 8 of the LED lamp 1, which photodiodes are designed to receive Li-Fi signals. The third receiver 118 has an electrical energy consumption greater than that of the first receiver 116 and of the second receiver 117. The third receiver 118 is designed to receive data at an intermediate or high rate, that is to say at a rate substantially greater than that of the first receiver 116 and of the second receiver 117.

The Li-Fi transmission module 105 includes a first Li-Fi signal emitter 120 and a second Li-Fi signal emitter 121. The first emitter 120 is a visible light emitter. The second emitter 121 is an infrared light emitter.

The first emitter 120 is connected to the light-emitting diodes 4 of the LED lamp 1, which diodes are designed to emit Li-Fi signals in the visible spectrum.

The second receiver 121 is connected to the second light-emitting diodes 6 of the LED lamp.

The first emitter 120 and the second emitter 121 each include shaping means in the electrical board making it possible to transform data to be transmitted, produced by the microcontroller 113, into data able to be used by the light-emitting diodes to emit the Li-Fi signals.

The first emitter 120 and the second emitter 121 have a relatively high electrical energy consumption and are designed to emit data at a high rate.

The memory module 106 here has a memory of EEPROM (for “Electrically Erasable Programmable Read-Only Memory”) type.

The user interface 107 makes it possible to connect, to the generic module 101, a display and an indicator LED for providing information to a user, as well as a keyboard and a pushbutton, so that the user is able to control the generic module 101 or make adjustments to the generic module 101 or to the device.

It is noted that, in the case of the LED lamp 1, the user interface is not used.

The external control interface 108 is an interface that enables the generic module 101 to control a device separate from the device in which the generic module 101 is integrated or a module separate from the generic module 101, said separate device or separate module being connected to the external control interface 108. The external control interface 108 also enables the separate device or the separate module to control the generic module 101.

It will be noted that, in the case of the LED lamp 1, the user interface is not used.

The measurement interface 109, for its part, makes it possible to connect sensors and detectors from the list presented earlier to the generic module 101 and to acquire data measured by these various sensors and detectors.

Here, the measurement interface is linked to the plurality of sensors and of detectors 9 of the LED lamp 1 via input ports 122 of the measurement interface.

The measurement interface 109 further includes an analog-to-digital converter 123 connected to the microcontroller 13. The analog-to-digital converter 123 converts analog voltages and currents resulting from the measurements performed by the sensors and detectors connected to the measurement interface 109 into digital signals that are able to be used by the microcontroller 113.

The light-energy-harvesting module 110 includes a light-energy-harvesting unit 124, a light energy conversion unit 125 and a light energy storage unit 126. The light-energy-harvesting unit 124 is intended to be linked to a photovoltaic cell (or to a plurality of photovoltaic cells grouped into a photovoltaic solar module) that converts an incident light power into electrical energy. The light energy conversion unit 125 shapes a voltage generated by this electrical energy in order to store it in the light energy storage unit 126. The energy storage unit 126 supplies the microcontroller 113 and the whole of the generic module 101 via a power management method managed by the energy management means 114 programmed in the microcontroller 113. It will be noted that the light-energy-harvesting unit 124 is also linked to the microcontroller 113 via an input 128 of the latter.

It will be noted that, in the case of the LED lamp, the light-energy-harvesting module 110 is not used.

With reference to FIG. 4, the electronic device capable of communicating by Li-Fi according to a second embodiment of the invention is here a lighting device of a second type 130.

The lighting device of a second type 130 here includes a housing 131 and a tubular LED lamp 132 to which the housing 131 is connected.

The housing 131 incorporates the generic module 101 described previously, an LED driver 133 for supplying the LED lamp 132, a rechargeable battery 134 and a recharging circuit associated with the battery 134.

The LED lamp 132 includes a photodiode 136 designed to receive Li-Fi signals in the visible spectrum and a photodiode 137 designed to receive Li-Fi signals in the infrared spectrum. The photodiodes 136, 137 are integrated into the LED lamp 132.

The LED lamp 132 also includes one or more light-emitting diodes 138 designed to emit Li-Fi signals in the visible spectrum and one or more light-emitting diodes 139 designed to emit Li-Fi signals in the infrared spectrum. The light-emitting diode(s) 139 are incorporated at a second end of the LED lamp 132.

The LED lamp 132 finally includes energy harvesting means 135 intended to harvest thermal energy produced by the light-emitting diodes 138 and 139. The energy harvesting means 135 are similar to the energy harvesting means 10 described earlier for the LED lamp 1. The first electrical energy generated by the energy harvesting means 135 is used here to store electricity in the battery 134 that supplies the generic module 101. It will be noted that the generic module 101 may also be supplied by a mains outlet.

The generic module 101 is connected to the LED lamp 132 via cables 140. The cables 140 link the generic module 101 to the energy harvesting means 135. The cables 140 also connect the photodiodes 136, 137 of the LED lamp 132 to the first 116, to the second 117 and to the third 118 Li-Fi signal receivers of the generic module 101. The cables 140 finally connect the light-emitting diodes 138, 139 of the LED lamp 132 to the first 120 and to the second 121 Li-Fi signal emitters of the generic module 101.

A plurality of sensors and of detectors 141 from the sensors and the detectors mentioned earlier are linked to the measurement interface 109 of the generic module 101 via second cables 142. The sensors and the detectors 141 perform various measurements of parameters of the environment of the lighting device 130.

With reference to FIG. 5, the electronic device capable of communicating by Li-Fi according to a third embodiment of the invention is here a mobile device of cell phone or tablet or laptop type, in this case a tablet 150.

The tablet 150 includes a photodiode 151 designed to receive Li-Fi signals in the visible spectrum and a photodiode 152 designed to receive Li-Fi signals in the infrared spectrum.

The tablet 150 furthermore includes a light-emitting diode 153 designed to emit Li-Fi signals in the visible spectrum and a light-emitting diode 154 designed to emit Li-Fi signals in the infrared spectrum.

The tablet 150 also includes energy harvesting means 156 intended to harvest thermal energy produced by the light-emitting diodes 153 and 154. The energy harvesting means 156 are similar to the energy harvesting means 10 described earlier for the LED lamp 1. The first electrical energy generated by the energy harvesting means 156 is used here to supply the generic module 101.

The generic module 101 is connected to the tablet 150 via connectors that link the photodiodes 151, 152 of the tablet 150 to the first 116, to the second 117 and to the third 118 Li-Fi signal receivers of the generic module 101, and the light-emitting diodes 153, 154 of the tablet 150 to the first 120 and to the second 121 Li-Fi signal emitters of the generic module 101. This generic module 101 may also be integrated into the tablet 150.

The tablet 150 furthermore includes a plurality of sensors and of detectors 155 from the sensors and the detectors mentioned earlier. The sensors and the detectors 155 are linked to the measurement interface 109 of the generic module 1. The sensors and the detectors 155 perform various measurements of parameters of the environment of the tablet 150.

With reference to FIG. 6, the electronic device capable of communicating by Li-Fi according to a fourth embodiment of the invention is here a measuring device 160. The measuring device 160 forms part of a network of sensors in which it performs measurements and acts as a repeater.

The measuring device 160 includes photodiodes, light-emitting diodes, the generic module 101, a plurality of sensors and of detectors 162, a battery 163 and a recharging circuit associated with the battery 163, and energy harvesting means 169.

The photodiodes comprise a photodiode 164 designed to receive Li-Fi signals in the visible spectrum and a photodiode 165 designed to receive Li-Fi signals in the infrared spectrum.

The light-emitting diodes comprise a light-emitting diode 166 designed to emit Li-Fi signals in the visible spectrum and a light-emitting diode 167 designed to emit Li-Fi signals in the infrared spectrum.

The photodiodes 164, 165 of the measuring device 160 are linked to the first 116 and to the second 117 Li-Fi signal receivers, respectively, and both to the third Li-Fi signal receiver 118 of the generic module 101, and the light-emitting diodes 166, 167 of the measuring device 160 are linked to the first 120 and to the second 121 Li-Fi signal emitters of the generic module 101.

The energy harvesting means comprise thermal-energy-harvesting means 169 intended to harvest thermal energy produced by the light-emitting diodes 166 and 167, as well as a photovoltaic solar module 161 including a plurality of photovoltaic cells.

The energy harvesting means 169 are similar to the energy harvesting means 10 described earlier for the LED lamp 1. The electrical energy generated by the energy harvesting means 169 is used here to supply the generic module 101.

The photovoltaic solar module 161, connected to the light-energy-harvesting unit 124 of the generic module 101, is intended to generate, from light energy, a second electrical energy intended to supply the measuring device 160. The two energy harvesting means 161 and 169 will store this energy in the form of electrical charge in the battery 163 used by the module 101.

The measuring device 160 is thus supplied by the battery 163, by the first electrical energy generated by the energy harvesting means 169 and by the second electrical energy originating from the light energy harvested by virtue of the photovoltaic solar module 161 connected to the light-energy-harvesting unit 124 of the generic module 101.

It is noted that the measuring device 160 may also be supplied by a mains outlet.

The sensors and the detectors 162 are linked to the measurement interface 109 of the generic module 101 and perform various measurements of parameters of the environment of the measuring device 160.

With reference to FIG. 7, the electronic device capable of communicating by Li-Fi according to a fifth embodiment of the invention is here a geolocation device 170.

The geolocation device 170 includes a geolocation module, energy harvesting means, photodiodes, light-emitting diodes, the generic module 101, a plurality of sensors and of detectors 172, a battery 173 and a recharging circuit associated with the battery, as well as a display 174.

The photodiodes comprise one or more photodiodes 175 designed to receive Li-Fi signals in the visible spectrum and one or more photodiodes 176 designed to receive Li-Fi signals in the infrared spectrum.

The light-emitting diodes comprise a light-emitting diode 177 designed to emit Li-Fi signals in the visible spectrum and a light-emitting diode 178 designed to emit Li-Fi signals in the infrared spectrum.

The photodiodes 175, 176 of the geolocation device 170 are linked to the first 116, to the second 117 and to the third 118 Li-Fi signal receivers of the generic module 101, and the light-emitting diodes 177, 178 of the geolocation device 170 are linked to the first 120 and to the second 121 Li-Fi signal emitters of the generic module 1.

The energy harvesting means comprise thermal-energy-harvesting means 179 intended to harvest thermal energy produced by the light-emitting diodes 177 and 178, as well as a photovoltaic solar module 171 including a plurality of photovoltaic cells.

The energy harvesting means 179 are similar to the energy harvesting means 10 described earlier for the LED lamp 1. The first electrical energy generated by the energy harvesting means 179 is stored in the battery 173. The generic module 101 is supplied by the battery 173.

The photovoltaic solar module 171, connected to the light-energy-harvesting unit 124 of the generic module 101, is intended to generate, from light energy, a second electrical energy intended for charging the battery 173 of the geolocation measurement device 170.

It is noted that the geolocation device 170 may also be supplied by a mains outlet.

The sensors and the detectors 172 of the geolocation device 170 are linked to the measurement interface 109 of the generic module 101 and perform various measurements of parameters of the environment of the geolocation device.

The display 174 is linked to the user interface 107 of the generic module 101 and makes it possible to display various pieces of information, including geolocation data produced by the geolocation device 170 and the measurement data.

With reference to FIG. 8, the electronic device capable of communicating by Li-Fi according to a sixth embodiment of the invention is here a portable speaker 180 of Bluetooth speaker type.

The portable speaker 180 includes a loudspeaker 181, photodiodes, light-emitting diodes, energy harvesting means 186, and a generic module 101.

The photodiodes comprise a photodiode 182 designed to receive Li-Fi signals in the visible spectrum and a photodiode 183 designed to receive Li-Fi signals in the infrared spectrum.

The light-emitting diodes comprise a light-emitting diode 184 designed to emit Li-Fi signals in the visible spectrum and a light-emitting diode 185 designed to emit Li-Fi signals in the infrared spectrum.

The photodiodes 182, 183 of the portable speaker 180 are linked to the first 116, to the second 117 and to the third 118 Li-Fi signal receivers of the generic module 101, and the light-emitting diodes 184, 185 of the portable speaker 180 are linked to the first 120 and to the second 121 Li-Fi signal emitters of the generic module 101.

The energy harvesting means 186 are intended to harvest thermal energy produced by the light-emitting diodes 184 and 185. The energy harvesting means 186 are similar to the energy harvesting means 10 described earlier for the LED lamp 1. The first electrical energy generated by the energy harvesting means 186 is used here to supply the generic module 101.

With reference to FIG. 9, the electronic device 190 capable of communicating by Li-Fi according to a seventh embodiment of the invention includes photodiodes, light-emitting diodes, a generic module 101, a display 191, a keyboard 192 and energy harvesting means 197.

The photodiodes comprise a photodiode 193 designed to receive Li-Fi signals in the visible spectrum and a photodiode 194 designed to receive Li-Fi signals in the infrared spectrum.

The light-emitting diodes comprise a light-emitting diode 195 designed to emit Li-Fi signals in the visible spectrum and a light-emitting diode 196 designed to emit Li-Fi signals in the infrared spectrum.

The photodiodes 193, 194 of the electronic device 190 are linked to the first 116, to the second 117 and to the third 118 Li-Fi signal receivers of the generic module 101, and the light-emitting diodes 195, 196 of the electronic device 190 are linked to the first 120 and to the second 121 Li-Fi signal emitters, respectively, of the generic module 101.

The energy harvesting means 197 are intended to harvest thermal energy produced by the light-emitting diodes 194 and 195. The energy harvesting means 197 are similar to the energy harvesting means 10 described earlier for the LED lamp 1. The first electrical energy generated by the energy harvesting means 197 is used here to supply the generic module 101.

The display 191 is linked to the user interface 107 of the generic module 101 and makes it possible to display various pieces of information relating, for example, to the communication of this device with the devices 130 and 150.

The display 191 here includes an electrically adaptable material of electrochromic, electrophoretic or liquid crystal-type. Such displays are described, for example, in the document E. L. Runnerstrom, A. Llordés, S. D. Lounis and D. J. Milliron, “Nanostructures electronic smart windows: traditional materials and NIR-selective plasmonic nanocrystals”, Chem. Commun., 50, 10555 (2014), as well as in the document C. G. Granqvist, “Oxide electrochromics: an introduction to devices and materials”, Solar Energy Materials & Solar Cells, 99, 1-13 (2012).

The keyboard 192 is linked to the user interface 107 of the generic module and enables a user to make various adjustments to the generic module 101 and to the electronic device 190.

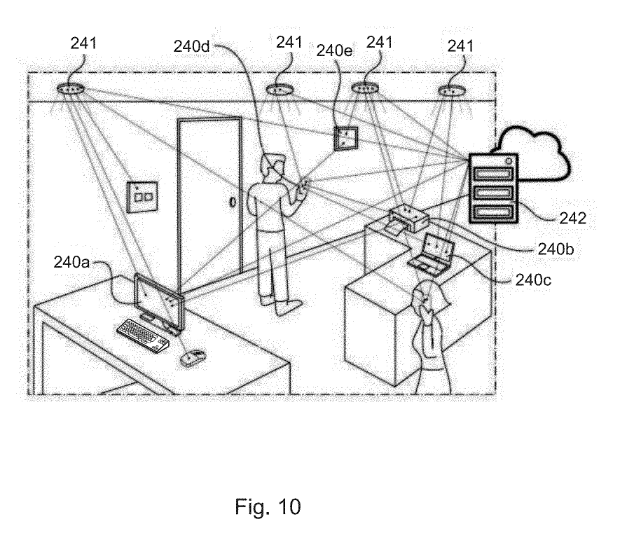

With reference to FIG. 10, a plurality of electronic devices 240 capable of communicating by Li-Fi of the invention are interconnected here in a network in a workspace illuminated by lamps 241 positioned on the ceiling of the workspace. Each electronic device 240 includes energy harvesting means such as the energy harvesting means 10 described earlier.

Among these electronic devices 240 are a computer screen 240a, a printer 240b, a laptop 240c, a cell phone 240d, a thermometer 240e, etc.

The network is managed by a server 242 that is linked to the lamps 241 in order to emit and receive Li-Fi signals.

Each electronic device 240 includes a generic module 101 of the invention and is designed to exchange Li-Fi signals with the other devices 240 of the network, on the one hand, and to exchange Li-Fi signals with the server 242 via the lamps 241, on the other hand.

The invention is not limited to the particular embodiment that has just been described, but, on the contrary, covers any variant within the scope of the invention as defined by the claims.

1. An electronic device capable of communicating by Li-Fi, the electronic device including:
at least one light-emitting diode intended to emit Li-Fi signals;
energy harvesting means intended to harvest thermal energy produced by the light-emitting diode and to generate, from the harvested thermal energy, a first electrical energy supply for the electronic device.

2. The electronic device as claimed in claim 1, wherein the energy harvesting means include a Peltier-type thermoelectric cell comprising a set of semi-conductors arranged between a thermally conductive hot plate and a thermally conductive cold plate, the hot plate being arranged in such a way that heat produced by the light-emitting diode heats the hot plate and establishes a temperature difference between the hot plate and the cold plate.

3. The electronic device as claimed in claim 2, wherein the energy harvesting means furthermore include a heat sink arranged in such a way as to establish a thermal conduction relationship with the cold plate.

4. The electronic device as claimed in claim 3, furthermore including a battery in which the first electrical energy is stored.

5. The electronic device as claimed in claim 1, wherein the electronic device includes an electronic module intended to control the light-emitting diode in order to emit Li-Fi signals, the electronic module being supplied at least partly by the first electrical energy.

6. The electronic device as claimed in claim 5, wherein the electronic device includes a first light-emitting diode designed to emit Li-Fi signals in the visible spectrum and a second light-emitting diode designed to emit Li-Fi signals in the infrared spectrum, and wherein the electronic module includes a first emitter, linked to the first light-emitting diode, for emitting Li-Fi signals in visible light and a second emitter, linked to the second light-emitting diode, for emitting Li-Fi signals in infrared light.

7. The electronic device as claimed in claim 5, wherein the electronic device includes a photodiode and wherein the electronic module includes a receiver linked to the photodiode for receiving Li-Fi signals.

8. The electronic device as claimed in claim 5, wherein the electronic device includes a sensor and wherein the electronic module includes a measurement interface linked to the sensor for acquiring measurements made by the sensor.

9. The electronic device as claimed in claim 5, wherein the electronic module includes a generic module designed to be fitted in different electronic devices or appliances capable of communicating by Li-Fi.

10. The electronic device as claimed in claim 1, wherein the energy harvesting means furthermore include a photovoltaic cell in-tended to generate, from light energy, a second electrical energy supply for the electronic device.

11. The electronic device as claimed in claim 1, the electronic device being a lighting device, or a mobile device of cell phone or tablet type, or a measuring device, or a geolocation device, or a portable speaker.

12. A network comprising a plurality of electronic devices as claimed in claim 1, the electronic devices being interconnected and communicating with one another by Li-Fi.
